(19) United States
(12) Patent Application Publication
(10) Pub. No.: US 2018/0254720 A1
(43) Pub. Date: Sep. 6, 2018

(54) POWER GENERATION DEVICE AND ELECTRONIC DEVICE PROVIDED WITH SAME

(71) Applicant: Panasonic Intellectual Property Management Co., Ltd., Osaka (JP)

(72) Inventor: SUGURU OHISHI, Okayama (JP)

(73) Assignee: Panasonic Intellectual Property Management Co., Ltd., Osaka (JP)

(21) Appl. No.: 15/760,327

(22) PCT Filed: Nov. 30, 2016
(86) PCT No.: PCT/JP2016/005019

§ 371 Date: Mar. 15, 2018

(30) Foreign Application Priority Data
Dec. 11, 2015 (JP) 2015-242510

(51) Int. Cl. H02N 2/18; H01L 41/113; H01H 13/06; H01H 13/14; H01H 13/20

(52) U.S. Cl. CPC H02N 2/186; H01L 41/1136; H01H 13/06; H01H 2235/01; H01H 13/20; H01H 2233/07; H01H 13/14

(57) ABSTRACT

A power generation device according to the present disclosure includes a housing, an operation unit that is movable in relation to the housing, a cantilevered vibrating body that has elasticity and is partly fixed to the housing, a piezoelectric element that is provided to the vibrating body and converts vibration energy of the vibrating body into electrical energy when the vibrating body is vibrated in a vibration direction, a slide piece that moves in conjunction with the operation unit and moves in a straight line between a first position and a second position in a sliding direction intersecting the vibration direction in relation to the housing, and a contact piece that is provided to the vibrating body, the contact piece being on a trajectory of the slide piece when the slide piece moves in the straight line, and being configured so as to be in contact with the slide piece and ride over the slide piece to thereby move in the vibration direction, when the slide piece moves from the first position to the second position.

### TECHNICAL FIELD

The present disclosure relates to a power generation device and an electronic device provided with the same, and more particularly to a power generation device that generates power by converting vibration energy into electrical energy by a piezoelectric element, and an electronic device provided with the same.

### BACKGROUND ART

There has conventionally been known a power generation device using a piezoelectric element (see PTL 1 and PTL 2, for example).

The power generation device disclosed in PTL 1 is provided with a ratchet-equipped gear which rotates in one direction by a lever moving in conjunction with a push button, a plate spring which is intermittently elastically deformed by the gear, and a piezoelectric element. The piezoelectric element generates an electromotive force by receiving an impact load from an elastic return force of the plate spring.

The power generation device disclosed in PTL 2 generates power by vibrating a vibrating piece having a piezoelectric layer. This power generation device transmits rotation energy of a rotation weight capable of rotating along a rotation surface to the vibrating piece as a vibration in a vertical direction by an excitation mechanism. The excitation mechanism has an excitation lever which swings in the vertical direction with the rotation of the rotation weight, wherein a vertical impact is applied to the vibrating piece by the excitation lever to excite a vertical vibration on the vibrating piece.

### CITATION LIST

### Patent Literature

PTL 1: Unexamined Japanese Patent Publication No. S55-137598

PTL 2: Unexamined Japanese Patent Publication No. H10-42577

### SUMMARY OF THE INVENTION

A power generation device according to one aspect of the present disclosure includes a housing, an operation unit which is movable in relation to the housing, a cantilevered vibrating body which has elasticity and is partly fixed to the housing, a piezoelectric element which is provided to the vibrating body and converts vibration energy of the vibrating body into electrical energy when the vibrating body is vibrated in a vibration direction, a slide piece which moves in conjunction with the operation unit and moves in a straight line between a first position and a second position in a sliding direction intersecting the vibration direction in relation to the housing, and a contact piece provided to the vibrating body, the contact piece being on a trajectory of the slide piece when the slide piece moves in the straight line, and being configured so as to be in contact with the slide piece and ride over the slide piece to thereby move in the vibration direction, when the slide piece moves from the first position to the second position.

An electronic device according to one aspect of the present disclosure includes the power generation device according to the one aspect, and a signal processing circuit electrically connected to the piezoelectric element of the power generation device.

### BRIEF DESCRIPTION OF DRAWINGS

FIG. 1A is a sectional view of an electronic device provided with a power generation device according to a first exemplary embodiment.

FIG. 1B is a schematic sectional view of a region indicated by Z1 in FIG. 1A.

FIG. 2 is a perspective view of the electronic device provided with the power generation device according to the first exemplary embodiment.

FIG. 3 is an exploded perspective view of the electronic device provided with the power generation device according to the first exemplary embodiment.

FIG. 4 is a sectional view of the electronic device provided with the power generation device according to the first exemplary embodiment with a second case and a signal processing circuit being removed.

FIG. 5A is an explanatory view for describing an operation when a slide piece of the power generation device moves from a first position to a second position.

FIG. 5B is an explanatory view for describing the operation when the slide piece of the power generation device moves from the first position to the second position.

FIG. 5C is an explanatory view for describing the operation when the slide piece of the power generation device moves from the first position to the second position.

FIG. 5D is an explanatory view for describing the operation when the slide piece of the power generation device moves from the first position to the second position.

FIG. 6A is an explanatory view for describing an operation when the slide piece of the power generation device moves from the second position to the first position.

FIG. 6B is an explanatory view for describing the operation when the slide piece of the power generation device moves from the second position to the first position.

FIG. 6C is an explanatory view for describing the operation when the slide piece of the power generation device moves from the second position to the first position.

FIG. 6D is an explanatory view for describing the operation when the slide piece of the power generation device moves from the second position to the first position.

FIG. 7A is a conceptual view illustrating a relative positional relation between the slide piece and a contact piece when the slide piece of the power generation device moves from the first position to the second position.

FIG. 7B is a conceptual view illustrating a relative positional relation between the slide piece and the contact piece when the slide piece of the power generation device moves from the second position to the first position.

FIG. 8 is a perspective view of a vibrating body and a contact piece of a power generation device according to a second exemplary embodiment.

### DESCRIPTION OF EMBODIMENTS

Prior to describing exemplary embodiments, a demand for a market with respect to the development of power generation devices will be described. Recently, depletion of fossil fuels in the future is becoming a significant problem because of an increase in power generation facilities using fossil fuels, particularly oil. In view of this, the development of stand-alone power generation devices without using fossil fuels has been demanded. Stand-alone power generation devices employing a system using water power, solar power, wind power, and ground heat, for example, to generate power have been known, but they need large-scale facilities.

On the other hand, a vibration power generation device that generates power by converting vibration energy into electrical energy by a piezoelectric element does not need large-scale facilities, so that it can be made more compact than devices employing a system using water power, solar power, wind power, and ground heat, for example, to generate power. Therefore, vibration power generation devices have a possibility of being mounted to a relatively compact electronic device. However, the power generation device of this type generates power by vibration energy applied to the piezoelectric element, so that, if the size of the power generation device is simply reduced, the amplitude of the vibration applied to the piezoelectric element becomes small, which may lead to a reduction in a power generation amount.

In addition, the conventional power generation devices described above need a rotary member (the gear in PTL 1 and the rotation weight and the excitation lever in PTL 2), and thus, need a space where the rotary member can rotate in a housing. Therefore, to reduce the size of the power generation device, the size of the rotary member needs to be decreased. However, if the size of the rotary member is decreased, the vibrating body (the plate spring in PTL 1 and the vibrating piece in PTL 2) becomes small, which may lead to a reduction in a power generation amount.

In view of this, the exemplary embodiments described below show, as one example, a vibration power generation device that can suppress a reduction in a power generation amount while achieving a reduction in size.

### First Exemplary Embodiment

### (1) Outline

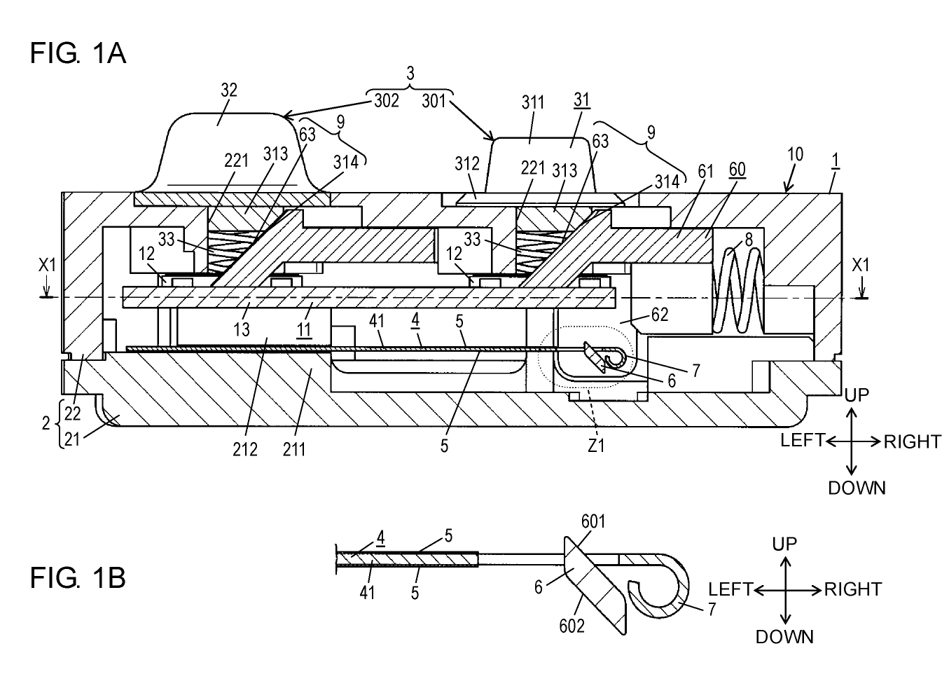

Power generation device 1 according to a first exemplary embodiment includes housing 2, operation unit 3, vibrating body 4, piezoelectric element 5, slide piece 6, and contact piece 7, as illustrated in FIGS. 1A and 1B.

Operation unit 3 is movable in relation to housing 2. Vibrating body 4 has elasticity and is configured to be cantilevered such that a part thereof is fixed to housing 2. Piezoelectric element 5 is provided to vibrating body 4. Piezoelectric element 5 converts vibration energy of vibrating body 4 into electrical energy when vibrating body 4 is vibrated in a vibration direction.

Slide piece 6 moves in conjunction with operation unit 3. Slide piece 6 moves in a straight line between a first position and a second position in a sliding direction that intersects the vibration direction in relation to housing 2. Contact piece 7 is provided to vibrating body 4. Contact piece 7 is positioned on a trajectory of slide piece 6 when slide piece 6 moves in a straight line. Contact piece 7 is configured so as to be in contact with slide piece 6 and ride over slide piece 6, thereby moving in the vibration direction, when slide piece 6 moves from the first position to the second position.

The “vibration direction” herein means a direction in which vibrating body 4 is vibrated. In the present exemplary embodiment, vibrating body 4 has a plate shape, and the vibration direction is a thickness direction of vibrating body 4, for example. The “sliding direction” herein means a direction in which slide piece 6 moves in a straight line in relation to housing 2. Slide piece 6 moves in a straight line between the first position and the second position, and therefore, the direction of the straight line connecting the first position and the second position is the “sliding direction”. The sliding direction and the vibration direction are not parallel to each other but intersect each other.

Further, it is only necessary that contact piece 7 is provided to vibrating body 4, and thus, contact piece 7 and vibrating body 4 may be integrally formed or separately formed. That is, contact piece 7 and vibrating body 4 may be formed integrally by using a single material, or contact piece 7 and vibrating body 4 may be formed from different materials and contact piece 7 may be coupled to vibrating body 4. Similarly, it is only necessary that piezoelectric element 5 is provided to vibrating body 4, and thus, piezoelectric element 5 and vibrating body 4 may be integrally formed or separately formed. That is, piezoelectric element 5 and vibrating body 4 may be formed integrally by using a single material, or piezoelectric element 5 and vibrating body 4 may be formed from different members and piezoelectric element 5 may be coupled to vibrating body 4.

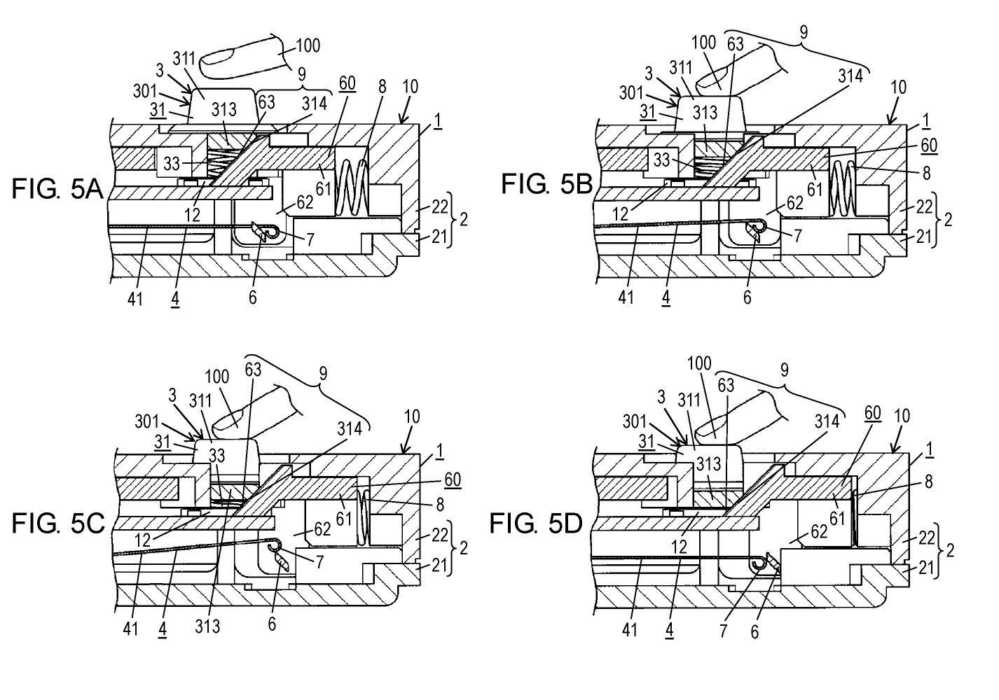

To sum up, in power generation device 1 according to the present exemplary embodiment, when operation unit 3 moves in relation to housing 2, slide piece 6 moves in the sliding direction in a straight line between the first position and the second position in conjunction with the movement of operation unit 3. Contact piece 7 is located on the trajectory of slide piece 6. Therefore, when slide piece 6 moves in a straight line, contact piece 7 is brought into contact with slide piece 6. When slide piece 6 moves from the first position to the second position, contact piece 7 being in contact with slide piece 6 rides over slide piece 6, thereby moving in the vibration direction. The detail of the operation of contact piece 7 riding over slide piece 6 will be described later with reference to FIGS. 5A to 5D. In other words, when slide piece 6 moves in the sliding direction to pass over contact piece 7, contact piece 7 is flipped by slide piece 6 and moves in the vibration direction. Thus, when slide piece 6 moves from the first position to the second position, a linear motion of slide piece 6 in the sliding direction is converted into a linear motion of contact piece 7 in the vibration direction. Due to contact piece 7 being provided to vibrating body 4, the movement of contact piece 7 in the vibration direction causes vibrating body 4 to vibrate in the vibration direction. When vibrating body 4 is vibrated, the vibration energy of vibrating body 4 is converted into electrical energy by piezoelectric element 5.

Accordingly, power generation device 1 according to the present exemplary embodiment vibrates vibrating body 4 with the movement of operation unit 3 when operation unit 3 is operated, thereby being capable of generating power by piezoelectric element 5. That is, power generation device 1 can generate power by an operation for operation unit 3.

Further, power generation device 1 according to the present exemplary embodiment is applicable to electronic device 10 as illustrated in FIG. 1A. Specifically, electronic device 10 according to the present exemplary embodiment includes power generation device 1 and signal processing circuit 11. Signal processing circuit 11 is electrically connected to piezoelectric element 5 of power generation device 1. Thus, electronic device 10 enables signal processing circuit 11 to activate by power generated by power generation device 1 due to operation unit 3 being operated. Accordingly, electronic device 10 does not additionally need a power supply from a non-rechargeable battery, a rechargeable battery, or a commercial power source, for example.

As described above, in power generation device 1 and electronic device 10 provided with power generation device 1 according to the present exemplary embodiment, vibrating body 4 is vibrated in the vibration direction with the movement of slide piece 6 from the first position to the second position along the sliding direction. An amount of movement of slide piece 6 in the sliding direction at that time may be equal to or more than a value obtained by adding the size of contact piece 7 in the sliding direction to the size of slide piece 6 in the sliding direction to enable contact piece 7 to ride over slide piece 6. The amount of movement of slide piece 6 and the amplitude of the vibration of vibrating body 4 do not directly relate to each other, and thus, a decrease in the amount of movement of slide piece 6 does not directly lead to a reduction in the power generation amount. Therefore, power generation device 1 that can suppress a reduction in the power generation amount while enabling a reduction in size, and electronic device 10 provided with the same are implemented.

### (2) Detail

Hereinafter, the detail of power generation device 1 according to the present exemplary embodiment and electronic device 10 provided with the same will be described with reference to the drawings. It should be noted that the configuration described below is merely one example of the present disclosure, and the present disclosure is not limited to the following exemplary embodiments. Therefore, besides the following exemplary embodiments, various modifications are possible depending on design or the like without departing from the scope of the technical idea of the present disclosure.

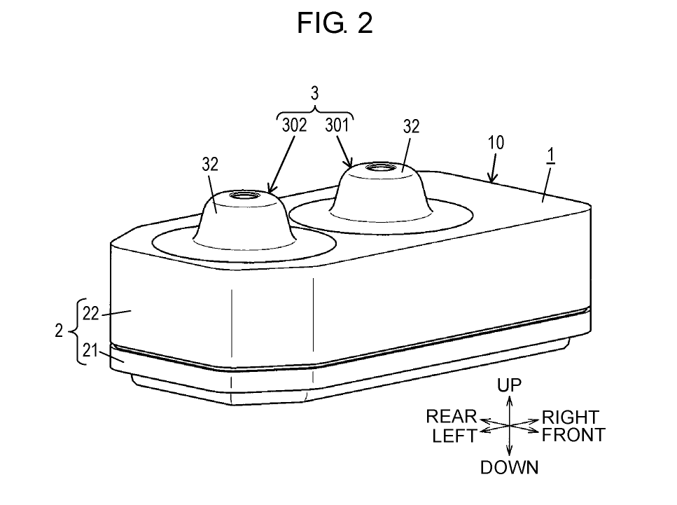

Unless otherwise specified, the “vibration direction” is defined as a vertical direction, and the “sliding direction” is defined as a horizontal direction in the following description. In addition, the direction in which operation unit 3 protrudes from the surface of housing 2 is defined as up, and the direction of movement of slide piece 6 when moving from the first position (position illustrated in FIG. 5A) to the second position (position illustrated in FIG. 5D) is defined as right in the following description. That is, up, down, left, and right are defined as indicated by an “up” arrow, a “down” arrow, a “left” arrow, and a “right” arrow in FIG. 1A or other drawings. In addition, in the following description, the direction orthogonal to the sheet surface of FIG. 1A is defined as a front-rear direction, wherein the near side is defined as a front. That is, front and rear are defined as indicated by a “front” arrow and a “rear” arrow in FIG. 2 or other drawings. However, it should be noted that these directions are not intended to specify the direction of use of power generation device 1. Further, the arrows indicating the respective directions in the drawings are merely illustrated for description, and they are unsubstantial.

In addition, in the present exemplary embodiment, it is supposed that the “vibration direction” and the “sliding direction” are mutually orthogonal. The wording “orthogonal” herein is used to include not only a state where both directions intersect strictly at a 90-degree angle but also a state where both directions are almost orthogonal to each other within a margin of error (in the following, the wording “orthogonal” has the same meaning)

### (2.1) Electronic Device

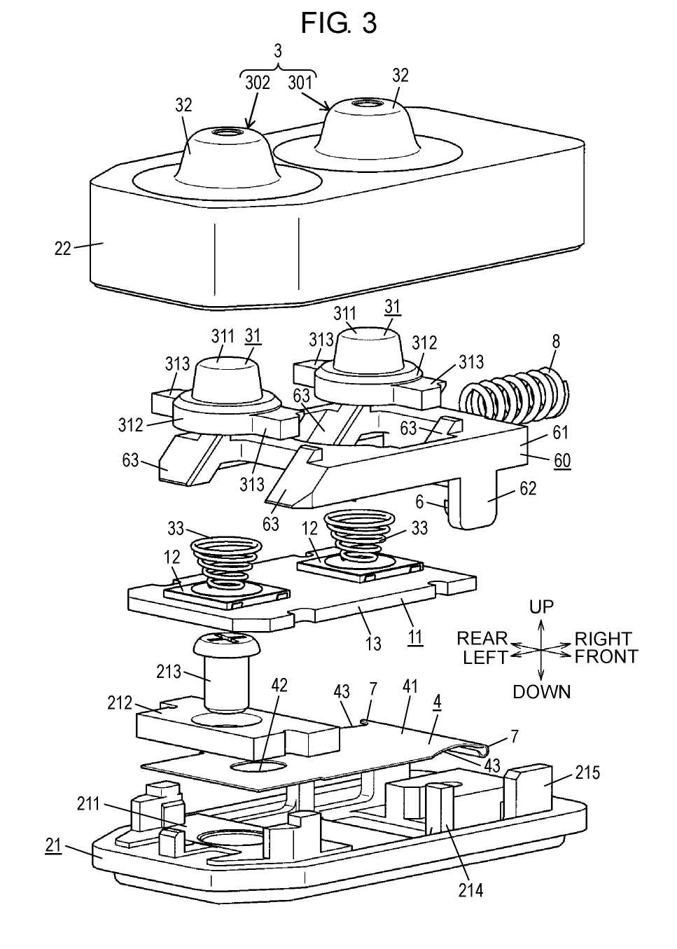

Firstly, electronic device 10 provided with power generation device 1 will be described with reference to FIGS. 1A to 3.

Electronic device 10 includes signal processing circuit 11 inside housing 2. Specifically, electronic device 10 shares housing 2 with power generation device 1, and components of power generation device 1 and components of electronic device 10 are provided in one housing 2.

Housing 2 is formed from a synthetic resin. Housing 2 has first case 21 and second case 22. First case 21 and second case 22 both have an opening. First case 21 and second case 22 constitute housing 2 by being joined to each other at peripheral ends of the openings. In the present exemplary embodiment, first case 21 and second case 22 are vertically assembled and joined such that first case 21 is on a lower side and second case 22 is on an upper side.

First case 21 and second case 22 are joined by laser welding, for example. Thus, intrusion of water into housing 2 of electronic device 10 from the joint portion between first case 21 and second case 22 can be prevented. In addition, electronic device 10 does not need a non-rechargeable battery or a rechargeable battery because of having power generation device 1. That is, a space for storing a non-rechargeable battery or a rechargeable battery is unnecessary in housing 2 of electronic device 10, and besides, housing 2 does not need a lid that allows access to the space. Therefore, intrusion of water from a gap between housing 2 and the lid can also be prevented. Accordingly, electronic device 10 according to the present exemplary embodiment is particularly suited for outdoor use.

Signal processing circuit 11 has printed substrate 13 and electronic components including switch 12. The electronic components are mounted on printed substrate 13. Signal processing circuit 11 includes electronic components composing a power supply circuit, a control circuit, a memory, a transmission circuit, and the like, in addition to switch 12.

Switch 12 is switched in conjunction with operation unit 3 and is in an on state only when operation unit 3 is pressed. That is, switch 12 is turned on when operator 100 (see FIG. 5A) operates operation unit 3. Therefore, signal processing circuit 11 can acquire an instruction from operator 100 through the operation for operation unit 3. Specifically, operation unit 3 has both a function as an operation unit to allow power generation device 1 to generate power and a function as an operation unit to give an instruction from operator 100 to signal processing circuit 11. According to this configuration, a number of components can be less than that in a configuration in which an operation unit for giving an instruction from operator 100 to signal processing circuit 11 is provided separately from operation unit 3 of power generation device 1. Note that FIG. 5A and other drawings illustrate a finger of operator 100.

The configurations of operation unit 3 and switch 12 will be described below in more detail. In the present exemplary embodiment, operation unit 3 has a plurality of (two in the present exemplary embodiment) operation elements 301 and 302 each of which is movable in relation to housing 2. As illustrated in FIG. 1A, the plurality of operation elements 301 and 302 are arranged adjacent to each other in the horizontal direction. A plurality of (two in the present exemplary embodiment) switches 12 is provided so as to correspond to the plurality of operation elements 301 and 302 one to one. The same configuration is applied for the combination of operation element 301 and switch 12 and the combination of operation element 302 and switch 12. Therefore, in the following description, unless otherwise specified, the operation element 301 and switch 12 will be described, and regarding operation element 302 and switch 12, the description for operation element 301 and switch 12 may be applied by replacing words and the description thereof will be omitted.

Operation element 301 is mounted to second case 22. Operation element 301 has button 31, waterproof rubber 32, and spring 33. Second case 22 is formed with through-hole 221 into which operation element 301 is to be mounted. In the present exemplary embodiment, through-hole 221 is circularly opened on a top surface of second case 22 and extends through second case 22 in the vertical direction. Note that waterproof rubber 32 for operation element 301 out of two operation elements 301 and 302 is not illustrated in FIGS. 1A and 5A to 6D.

Button 31 is formed from a synthetic resin. Button 31 has protrusion 311, flange 312, and a pair of pressing pieces 313. Flange 312 has a shape of a vertically flat disk. Protrusion 311 is formed into a columnar shape protruding upward from a central part of a top surface of flange 312. The pair of pressing pieces 313 protrudes toward either end in the front-rear direction from the outer peripheral surface of flange 312. Button 31 is mounted to second case 22 such that protrusion 311 penetrates through-hole 221 from the inside of housing 2. Thus, at least a tip (upper end) of protrusion 311 protrudes upward from the top surface of housing 2 through through-hole 221.

Waterproof rubber 32 is fixed to the peripheral edge of through-hole 221 on the top surface of second case 22. Waterproof rubber 32 is formed into a dome shape for covering through-hole 221 and protrusion 311. Waterproof rubber 32 has sufficient flexibility such that button 31 can be pressed over waterproof rubber 32. The top surface of flange 312 faces the lower surface of waterproof rubber 32 or second case 22. Specifically, the contact between flange 312 and the inner surface of waterproof rubber 32 or second case 22 regulates the protruding amount of protrusion 311 from the top surface of housing 2 to be equal to or lower than a prescribed amount. Note that, preferably, waterproof rubber 32 and second case 22 are integrally formed by two-shot injection molding, for example. This configuration can prevent formation of a gap between waterproof rubber 32 and second case 22 of electronic device 10, thereby being capable of preventing intrusion of water or the like into housing 2. Accordingly, electronic device 10 according to the present exemplary embodiment is particularly suited for outdoor use.

Switch 12 is disposed at a position corresponding to button 31, that is, below through-hole 221, on a top surface of printed substrate 13 stored in housing 2. Spring 33 is disposed to be sandwiched between flange 312 of button 31 and switch 12.

According to the configuration described above, in a state where button 31 is not pressed, i.e., in a steady state, button 31 is located at an upper end of a range of movement by an elastic force of spring 33. The position of operation element 301 (operation unit 3) at that time is referred to as a “reference position” below. When operation element 301 is at the reference position, switch 12 corresponding to operation element 301 is turned off. When being pressed, button 31 moves downward from the reference position to compress spring 33, and the downward force applied to button 31 is transmitted to switch 12 through spring 33. The position of operation element 301 (operation unit 3) at that time is referred to as an “operation position” below. When operation element 301 is at the operation position, switch 12 is turned on. When the force for pushing button 31 becomes absent, operation element 301 returns to the reference position by the elastic force of spring 33, so that switch 12 is turned off.

To sum up, operation unit 3 moves in a straight line between the reference position and the operation position along the vertical direction according to the operation by operator 100. When operation unit 3 is at the reference position, which is in a steady state, switch 12 is turned off, and when operation unit 3 is at the operation position, switch 12 is turned on. Thus, operation unit 3 and switch 12 constitute a momentary push button switch in which switch 12 is on only when operation unit 3 is pressed.

Meanwhile, electronic device 10 preferably has a capacitor between signal processing circuit 11 and piezoelectric element 5 so as to be electrically connected to signal processing circuit 11 and piezoelectric element 5. According to this configuration, electronic device 10 can store charges generated from piezoelectric element 5 into the capacitor, thereby being capable of stably applying a voltage equal to or higher than the minimum operating voltage of signal processing circuit 11 to signal processing circuit 11.

### (2.2) Power Generation Device

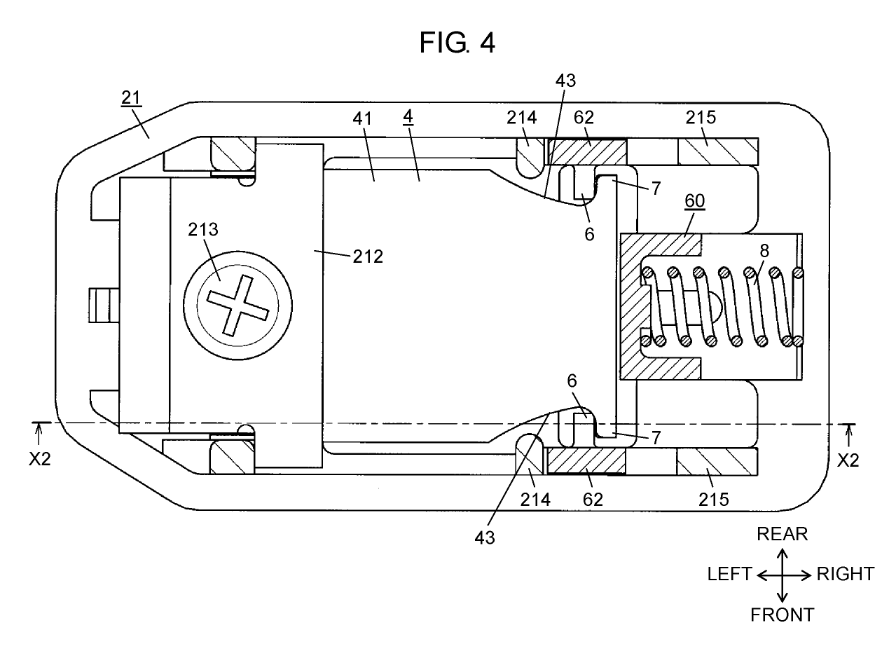

Next, the configuration of power generation device 1 will be described with reference to FIGS. 1A to 4. FIG. 4 is a sectional view, taken along line X1-X1 in FIG. 1A, of electronic device 10 from which second case 22 and signal processing circuit 11 are removed. FIG. 1A is a sectional view along line X2-X2 in FIG. 4.

Power generation device 1 according to the present exemplary embodiment further includes slider 60, return spring 8, and link mechanism 9, in addition to housing 2, operation unit 3, vibrating body 4, piezoelectric element 5, slide piece 6, and contact piece 7. Among the components of power generation device 1, housing 2 and operation unit 3 are shared by power generation device 1 and electronic device 10.

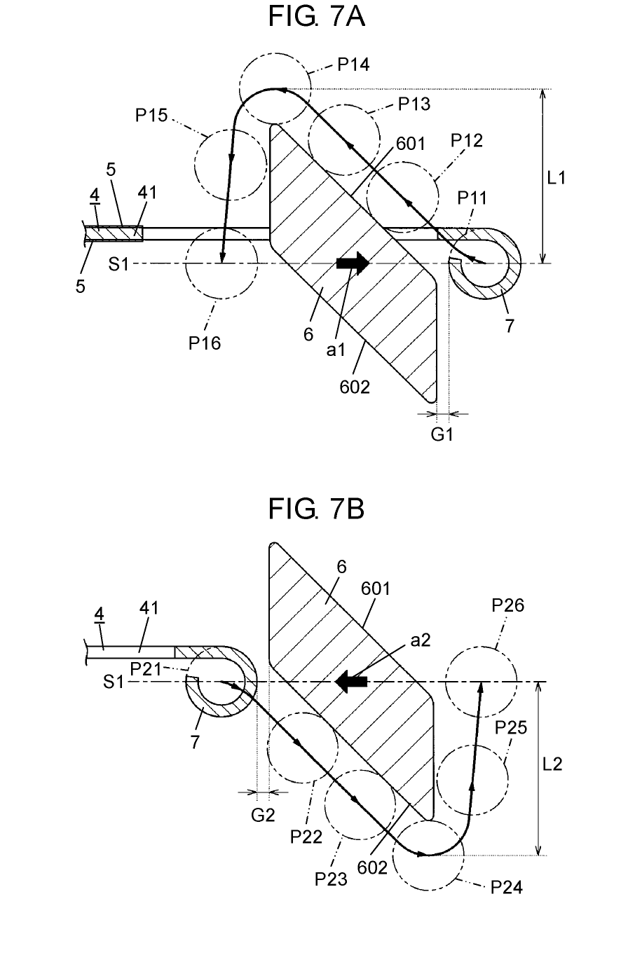

Vibrating body 4 and piezoelectric element 5 are provided inside housing 2. Vibrating body 4 has a rectangular elastic plate 41 which is long in the horizontal direction in a plan view. Elastic plate 41 is formed from a plate material having elasticity, such as a metal plate made of stainless (SUS), for example. Piezoelectric element 5 is mounted on both surfaces of elastic plate 41 in the thickness direction (vertical direction) as illustrated in FIG. 1B. Thus, vibrating body 4 and piezoelectric element 5 are integrally formed. Piezoelectric element 5 is attached to elastic plate 41 by bonding, for example. Note that piezoelectric element 5 is not illustrated in the drawings other than FIG. 1B and FIG. 7A.

Vibrating body 4 has a cantilevered structure with one end (left end in the present exemplary embodiment) in the longitudinal direction (horizontal direction) being defined as a fixed end and the other end (right end in the present exemplary embodiment) being defined as a free end. Due to the deformation of elastic plate 41, the right end serving as the free end of cantilevered vibrating body 4 can be vibrated in the vertical direction which is the thickness direction of elastic plate 41. The vertical vibration of elastic plate 41 causes distortion of piezoelectric element 5, whereby piezoelectric element 5 generates power. Specifically, vibration energy of elastic plate 41 in the vertical direction (vibration direction) is converted into electrical energy by piezoelectric element 5.

In the present exemplary embodiment, the fixed end (left end) of elastic plate 41 is fixed to first case 21 and held by housing 2. Specifically, elastic plate 41 is held by housing 2 such that the left end of elastic plate 41 is nipped between mounting base 211 and mounting plate 212 provided on the inner surface of first case 21. Elastic plate 41 is formed with mounting hole 42, and mounting plate 212 is fixed to mounting base 211 by mounting screw 213 through mounting hole 42.

Contact piece 7 is provided to vibrating body 4. In the present exemplary embodiment, the free end (right end) of elastic plate 41 is bent downward in an arc with a predetermined diameter in a front view. Specifically, the right end of elastic plate 41 is curled by bending. The bent part in an arc constitutes contact piece 7. In this way, vibrating body 4 and contact piece 7 are integrally formed in the present exemplary embodiment. Although described later in detail, contact piece 7 is formed at multiple locations (two in the present exemplary embodiment) distant from each other along a “width direction” which is a short direction of elastic plate 41. That is, vibrating body 4 is provided with two contact pieces 7 distant from each other in the width direction. The “width direction” herein means a direction orthogonal to both the sliding direction (horizontal direction) and the vibration direction (vertical direction), and in the present exemplary embodiment, the width direction is a front-rear direction.

In addition, on the left of each of a pair of contact pieces 7 of vibrating body 4, cutouts 43 for making the size of vibrating body 4 in the width direction smaller than the size of vibrating body 4 at other parts are formed, as illustrated in FIG. 4. Due to cutouts 43 being formed, vibrating body 4 can avoid an interference with slide piece 6 which is at the first position (the state in FIG. 4).

Slide piece 6 is a portion of slider 60. Slider 60 is configured so as to move in conjunction with operation unit 3 and move in a straight line in the horizontal direction in relation to housing 2. Slider 60 is stored in housing 2. Slider 60 is formed from a synthetic resin. Slider 60 is formed into a rectangular frame shape.

Slider 60 has frame body 61 having a rectangular frame shape, and a pair of projecting pieces 62 projecting downward from the lower surface of frame body 61. Slider 60 is disposed in housing 2 such that frame body 61 is located between second case 22 and signal processing circuit 11 (printed substrate 13). Inclined surface 63 inclined to the left is formed on the top surface of frame body 61 at a position facing pressing piece 313 of button 31. In the present exemplary embodiment, operation unit 3 has two buttons 31, and a pair of pressing pieces 313 is provided for each button 31, so that there are four pressing pieces 313. Therefore, inclined surface 63 is formed at four locations corresponding to four pressing pieces 313. In addition, the surface of pressing piece 313 facing inclined surface 63 is pressing surface 314 parallel to inclined surface 63.

Projecting piece 62 is provided at both ends of frame body 61 in the front-rear direction. A pair of projecting pieces 62 has a plate shape whose thickness direction corresponds to the front-rear direction (width direction), and they face each other in the front-rear direction. First regulation piece 214 and second regulation piece 215 are provided at both sides of each of the pair of projecting pieces 62 in the horizontal direction. First regulation piece 214 and second regulation piece 215 are provided to first case 21 so as to project upward from the top surface of first case 21.

Further, return spring 8 is provided between a right side surface of frame body 61 and the inner surface of second case 22 in a compressed state. Accordingly, return spring 8 exerts a force for pushing slider 60 in one direction in the horizontal direction (to the left in the present exemplary embodiment) on slider 60.

According to the configuration described above, slider 60 moves in the horizontal direction in relation to housing 2 in conjunction with the operation of operation unit 3. Specifically, when operation unit 3 moves in a straight line between the reference position and the operation position along the vertical direction, slider 60 moves in the horizontal direction intersecting the vertical direction with the movement of operation unit 3.

Specifically, in a state where operation unit 3 is not pressed, i.e., in a steady state, slider 60 is located at a left end of the range of movement by an elastic force of return spring 8. The position of slider 60 at that time is referred to as a “start position” below. On the other hand, when operation unit 3 is pressed and moved from the reference position to the operation position, button 31 moves downward, so that pressing surface 314 of button 31 is pressed against inclined surface 63 of slider 60. When button 31 moves downward in this state, slider 60 receives a rightward force from pressing surface 314 at inclined surface 63, thereby moving to the right in a straight line. Thus, slider 60 moves to the right end of the range of movement while compressing return spring 8. The position of slider 60 at that time is referred to as a “terminal position” below. Then, when the force for pushing operation unit 3 is absent, operation unit 3 returns to the reference position, so that button 31 moves upward. At that time, the force of pressing surface 314 of button 31 for pressing inclined surface 63 of slider 60 is absent, and therefore, slider 60 returns to the start position by the elastic force of return spring 8. Further, when slider 60 moves to the left by the elastic force of return spring 8 while returning to the start position, button 31 receives a leftward force from the inclined surface 63 at pressing surface 314, thereby moving upward in a straight line.

To sum up, in the present exemplary embodiment, the movement of operation unit 3 is transmitted to slider 60 by pressing surface 314 being pressed against inclined surface 63, and thus, slider 60 moves in conjunction with operation unit 3. In other words, pressing surface 314 and inclined surface 63 constitute link mechanism 9 that allows slider 60 to move in conjunction with operation unit 3. In the present exemplary embodiment, the movement of operation unit 3 in the vertical direction (vibration direction) is converted into the movement of slider 60 in the horizontal direction (sliding direction) orthogonal to the vertical direction (vibration direction) by link mechanism 9. As described above, button 31 of operation unit 3 has a function of sliding slider 60 as well as a function of switching on/off of switch 12.

In the present exemplary embodiment, operation unit 3 has two operation elements 301 and 302 each of which is movable in relation to housing 2, as described above. Also, four sets of pressing surface 314 and inclined surface 63 are provided so as to correspond to two buttons 31. That is, link mechanism 9 is configured to move slide piece 6 in the horizontal direction by the movement of at least one of the plurality of operation elements 301 and 302.

Moreover, first regulation piece 214 and second regulation piece 215 are provided at both sides of each of the pair of projecting pieces 62 in the horizontal direction, whereby the range of movement of slider 60 in the horizontal direction is regulated by first regulation piece 214 and second regulation piece 215. That is, the position where each of a pair of projecting pieces 62 is in contact with first regulation piece 214 is the left end (start position) of the range of movement of slider 60. On the other hand, the position where each of the pair of projecting pieces 62 is in contact with second regulation piece 215 is the right end (terminal position) of the range of movement of slider 60.

Meanwhile, the pair of projecting pieces 62 is located at both sides of the free end (right end) of vibrating body 4 in the front-rear direction. Slide piece 6 is formed on the surface of each of the pair of projecting pieces 62 facing vibrating body 4. Slide piece 6 is a part of slider 60. Therefore, so long as slider 60 moves in conjunction with operation unit 3, slide piece 6 moves in conjunction with operation unit 3. Accordingly, slide piece 6 moves in a straight line between the first position and the second position in the horizontal direction in relation to housing 2.

Herein, the position of slide piece 6 when operation unit 3 is at the reference position is referred to as the “first position” of slide piece 6 in the present exemplary embodiment. On the other hand, the position of slide piece 6 when operation unit 3 is at the operation position is referred to as the “second position” of slide piece 6 in the present exemplary embodiment. In other words, the position of slide piece 6 when slider 60 is at the start position is the “first position”, and the position of slide piece 6 when slider 60 is at the terminal position is the “second position”.

Herein, contact piece 7 is located on a trajectory of slide piece 6 when slide piece 6 moves in a straight line. That is, slide piece 6 is provided at a position facing contact piece 7 in the horizontal direction as illustrated in FIG. 1A. It should be noted that the position of contact piece 7 here is a position of contact piece 7 in a state where vibrating body 4 is not vibrated. When slide piece 6 moves from the first position to the second position, contact piece 7 is in contact with slide piece 6 and rides over slide piece 6, thereby moving in the vertical direction.

Specifically, in the present exemplary embodiment, when slide piece 6 is at the first position, slide piece 6 is located at the left side of contact piece 7 as illustrated in FIG. 1B. When moving from the first position to the second position along the horizontal direction, slide piece 6 moves to the right in relation to contact piece 7. When doing so, slide piece 6 passes over contact piece 7 in the horizontal direction and moves to the right of contact piece 7. In other words, when slide piece 6 moves to the second position from the first position, the relative positional relation between contact piece 7 and slide piece 6 is switched. When slide piece 6 is at the first position, contact piece 7 is located on the right of slide piece 6, and when slide piece 6 is at the second position, contact piece 7 is located on the left of slide piece 6.

More specifically, the sectional shape of slide piece 6 in the direction orthogonal to the front-rear direction is as illustrated in FIG. 1B. One surface of slide piece 6 in the vertical direction (top surface in the present exemplary embodiment) serves as first guide surface 601 inclined with respect to the horizontal direction so as to face contact piece 7 in the horizontal direction when slide piece 6 is at the first position. Specifically, in the state where slide piece 6 is at the first position, contact piece 7 is on the right side of slide piece 6, and in this regard, the top surface of slide piece 6 constitutes first guide surface 601 inclined to the right. In addition, one surface of slide piece 6 in the vertical direction (bottom surface in the present exemplary embodiment) serves as second guide surface 602 inclined with respect to the horizontal direction so as to face contact piece 7 in the horizontal direction when slide piece 6 is at the second position. Specifically, in the state where slide piece 6 is at the second position, contact piece 7 is on the left side of slide piece 6, and in this regard, the bottom surface of slide piece 6 constitutes second guide surface 602 inclined to the left.

In the present exemplary embodiment, a right side surface (first end face) and a left side surface (second end face) of slide piece 6 are flat surfaces orthogonal to the horizontal direction and are parallel to each other. In addition, first guide surface 601 connecting the upper end of the right side surface and the upper end of the left side surface of slide piece 6 and second guide surface 602 connecting the lower end of the right side surface and the lower end of the left side surface of slice piece 6 are parallel to each other. Therefore, the sectional shape of slide piece 6 in the direction orthogonal to the front-rear direction is a parallelogram as illustrated in FIG. 1B. Four corners (upper-left corner, lower-left corner, upper-right corner, and lower-right corner) of slide piece 6 are rounded to have a curved surface. However, forming the corners of slide piece 6 into a curved surface is not always necessary for power generation device 1.

The horizontal size of slide piece 6 is relevant to the amount of movement of slide piece 6 when slide piece 6 moves from the first position to the second position, and the vertical size of slide piece 6 is relevant to the displacement amount of contact piece 7. Therefore, to ensure large amplitude of the vibration of vibrating body 4 with a smaller amount of movement of slide piece 6, it is preferable that the vertical size of slide piece 6 is larger than the horizontal size of slide piece 6. Specifically, the larger an aspect ratio of the cross section of slide piece 6 orthogonal to the front-rear direction is, the larger amplitude of the vibration of vibrating body 4 can be ensured with respect to the amount of movement of slide piece 6. In the present exemplary embodiment, the right side surface and the left side surface of slide piece 6 are both erected along the vertical direction, whereby the horizontal size of slide piece 6 can be relatively reduced. Thus, the amount of movement of slide piece 6 in the horizontal direction can be decreased.

In addition, during assembly of power generation device 1 according to the present exemplary embodiment, it is preferable that, firstly, vibrating body 4 is mounted to first case 21, and then, operation unit 3 is mounted to second case 22. Then, signal processing circuit 11 (printed substrate 13) is further fixed to first case 21. During this process, printed substrate 13 is fixed to first case 21 by thermal caulking, for example. On the other hand, slider 60 and return spring 8 are incorporated into second case 22. Then, first case 21 and second case 22 are combined and joined to each other, whereby power generation device 1 is completed.

### (2.3) Operation

Hereinafter, operations of power generation device 1 and electronic device 10 according to the present exemplary embodiment will be described with reference to FIGS. 5A to 7B. FIG. 7A is a schematic view illustrating the movement of contact piece 7 when slide piece 6 moves in a direction of arrow a1 (to the right) to the second position from the first position. Circles (two-dot chain line) indicated by P11 to P16 in FIG. 7A are virtual circles including the outer periphery of contact piece 7, and indicate the position of contact piece 7 in chronological order. FIG. 7B is a schematic view illustrating the movement of contact piece 7 when slide piece 6 moves in a direction of arrow a2 (to the left) to the first position from the second position. Circles (two-dot chain line) indicated by P21 to P26 in FIG. 7B are virtual circles including the outer periphery of contact piece 7, and indicate the position of contact piece 7 in chronological order.

Firstly, the operation of power generation device 1 when slide piece 6 moves from the first position to the second position will be described with reference to FIGS. 5A to 5D. FIGS. 5A to 5D illustrate the operation when operation element 301 which is one of two operation elements 301 and 302 is operated, and do not illustrate the left part which is horizontally a half of electronic device 10 divided between two operation elements 301 and 302.

That is, in a state where operator 100 does not operate operation unit 3, slide piece 6 is at the first position as illustrated in FIG. 5A. At that time, operation unit 3 (button 31) is at the reference position, and slider 60 is at the start position. Switch 12 is off. With this state, gap G1 (see FIG. 7A) is formed between slide piece 6 and contact piece 7.

When operator 100 operates operation unit 3 (presses button 31), operation unit 3 (button 31) moves downward from the reference position, and in conjunction with this movement, slider 60 moves to the right from the start position as illustrated in FIG. 5B. Therefore, slide piece 6 provided on slider 60 moves to the right from the first position. Due to the movement of slide piece 6 to the right relative to contact piece 7, gap G1 between slide piece 6 and contact piece 7 is eliminated, and thus, slide piece 6 is brought into contact with contact piece 7. At that time, slide piece 6 is brought into contact with contact piece 7 at first guide surface 601. Accordingly, due to the movement of slide piece 6 to the right, contact piece 7 displaces upward along first guide surface 601 while warping vibrating body 4.

When operator 100 further presses operation unit 3 (button 31) from the state in FIG. 5B, operation unit 3 (button 31) further moves downward, and in conjunction with this movement, slider 60 further moves to the right. Thus, contact piece 7 keeps displacing upward along first guide surface 601 while warping vibrating body 4, and reaches the left end of first guide surface 601 as illustrated in FIG. 5C. At that time, the displacement amount of contact piece 7 and the amount of warp of vibrating body 4 in the vertical direction from the state illustrated in FIG. 5A are the maximum. That is, the displacement amount of contact piece 7 in the vertical direction in the state illustrated in FIG. 5C is maximum displacement amount L1 (see FIG. 7A).

When operator 100 further presses operation unit 3 (button 31) from the state illustrated in FIG. 5C, operation unit 3 (button 31) further moves downward, and in conjunction with this movement, slider 60 further moves to the right. Then, as illustrated in FIG. 5D, operation unit 3 (button 31) moves to the operation position, and slider 60 moves to the terminal position. Thus, switch 12 is turned on. From the state in FIG. 5C to the state in FIG. 5D, contact piece 7 rides over the left end of first guide surface 601, that is, the corner between first guide surface 601 and the left side surface, so that contact piece 7 is away from first guide surface 601 and flipped. Specifically, in the state in FIG. 5D, slide piece 6 moves to the right of contact piece 7 beyond contact piece 7, and thus, the support by slide piece 6, which displaces contact piece 7, from below becomes absent. Therefore, contact piece 7 is flipped downward by the elastic force of vibrating body 4.

Specifically, when slide piece 6 moves to the second position from the first position, the relative positional relation between slide piece 6 and contact piece 7 is changed as illustrated in FIG. 7A. That is, in the state where slide piece 6 is at the first position, contact piece 7 is at a position indicated by “P11” with respect to slide piece 6, and gap G1 is ensured between slide piece 6 and contact piece 7. A virtual plane passing through the center axis (the center of virtual circle P11) of contact piece 7 at that time and orthogonal to the vertical direction is defined as reference plane S1. When slide piece 6 moves in the direction of arrow a1 from this state, contact piece 7 displaces upward along first guide surface 601 as indicated by “P12” and “P13”.

Then, after reaching the upper end of slide piece 6, that is, reaching a position indicated by “P14”, contact piece 7 displaces downward as indicated by “P15” and “P16”. When contact piece 7 moves to a position indicated by “P16” from the position indicated by “P14” during the downward displacement, contact piece 7 is swiftly flipped downward by the elastic force of vibrating body 4 which remains warped. Therefore, even after slide piece 6 moves to the second position, that is, contact piece 7 moves to the position indicated by “P16”, contact piece 7 continues to vibrate in the vertical direction by the elasticity of vibrating body 4. However, the vibration of contact piece 7 gradually attenuates. When the vibration of contact piece 7 is stopped, contact piece 7 stops at the position indicated by “P16”, that is, the position where the center axis (center of virtual circle P16) of contact piece 7 passes through reference plane S1.

As described above, when slide piece 6 passes over contact piece 7 in the horizontal direction during the movement from the first position to the second position, contact piece 7 being in contact with slide piece 6 rides over slide piece 6, thereby moving in the vertical direction. Due to contact piece 7 being provided to vibrating body 4, after slide piece 6 passes over contact piece 7, vibrating body 4 is vibrated in the vertical direction, and the vibration energy of vibrating body 4 is converted into electrical energy by piezoelectric element 5. Thus, power generation device 1 generates power.

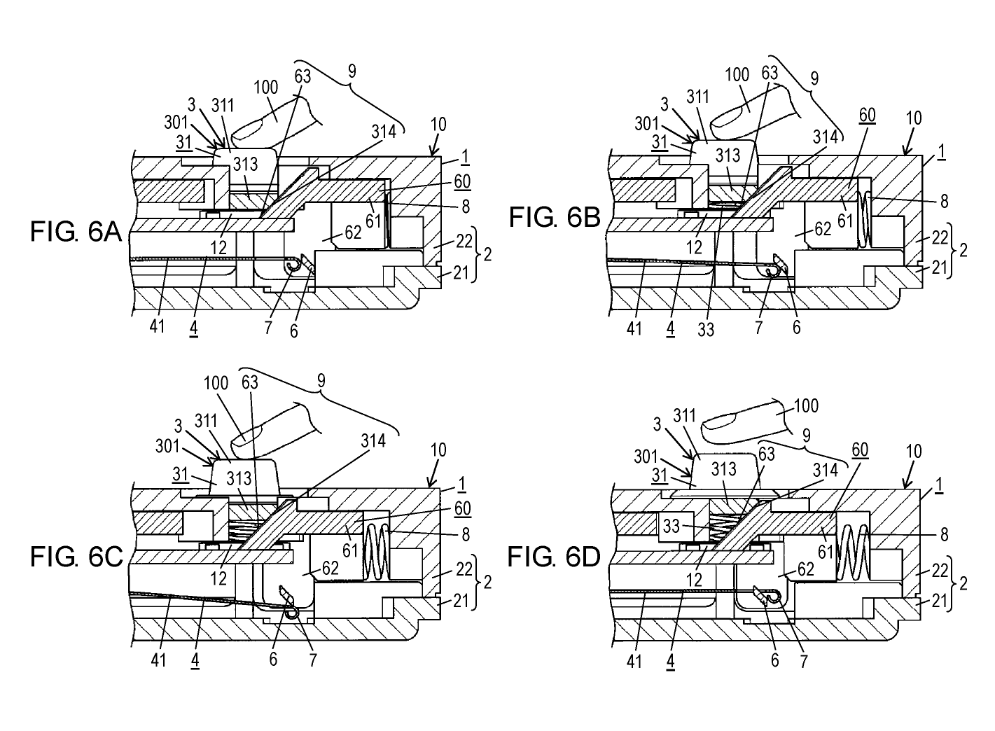

Next, the operation of power generation device 1 when slide piece 6 moves from the second position to the first position will be described with reference to FIGS. 6A to 6D. FIGS. 6A to 6D illustrate the operation when operation element 301 which is one of two operation elements 301 and 302 is operated, and do not illustrate the left part which is horizontally a half of electronic device 10 divided between two operation elements 301 and 302.

That is, in a state where operator 100 operates operation unit 3 (presses button 31), slide piece 6 is at the second position as illustrated in FIG. 6A. At that time, operation unit 3 (button 31) is at the operation position, and slider 60 is at the terminal position. Switch 12 is on. With this state, gap G2 (see FIG. 7B) is formed between slide piece 6 and contact piece 7.

When the operation for operation unit 3 by operator 100 is canceled (operator 100 releases his/her finger from button 31), slider 60 moves to the left from the terminal position by the elastic force of return spring 8, and in conjunction with this movement, operation unit 3 (button 31) moves upward from the operation position as illustrated in FIG. 6B. Therefore, slide piece 6 provided on slider 60 moves to the left from the second position. Due to the movement of slide piece 6 to the left relative to contact piece 7, gap G2 between slide piece 6 and contact piece 7 is eliminated, and thus, slide piece 6 is brought into contact with contact piece 7. At that time, slide piece 6 is brought into contact with contact piece 7 at second guide surface 602. Accordingly, due to the movement of slide piece 6 to the left, contact piece 7 displaces downward along second guide surface 602 while warping vibrating body 4.

Slider 60 further moves to the left from the state in FIG. 6B. Thus, contact piece 7 keeps displacing downward along second guide surface 602 while warping vibrating body 4, and reaches the right end of second guide surface 602 as illustrated in FIG. 6C. At that time, the displacement amount of contact piece 7 and the amount of warp of vibrating body 4 in the vertical direction from the state illustrated in FIG. 6A are the maximum. That is, the displacement amount of contact piece 7 in the vertical direction in the state illustrated in FIG. 6C is maximum displacement amount L2 (see FIG. 7B).

Slider 60 further moves to the left from the state in FIG. 6C, and in conjunction with this movement, operation unit 3 (button 31) further moves upward. Then, as illustrated in FIG. 6D, operation unit 3 (button 31) moves to the reference position, and slider 60 moves to the start position. Thus, switch 12 is turned off. From the state in FIG. 6C to the state in FIG. 6D, contact piece 7 rides over the right end of second guide surface 602, that is, the corner between second guide surface 602 and the right side surface, so that contact piece 7 is away from second guide surface 602 and flipped. Specifically, in the state in FIG. 6D, slide piece 6 moves to the left of contact piece 7 beyond contact piece 7, and thus, the support by slide piece 6, which displaces contact piece 7, from above becomes absent. Therefore, contact piece 7 is flipped upward by the elastic force of vibrating body 4.

To sum up, when slide piece 6 moves to the first position from the second position, the relative positional relation between slide piece 6 and contact piece 7 is changed as illustrated in FIG. 7B. That is, in the state where slide piece 6 is at the second position, contact piece 7 is at a position indicated by “P21” with respect to slide piece 6, and gap G2 is ensured between slide piece 6 and contact piece 7. A virtual plane passing through the center axis (the center of virtual circle P21) of contact piece 7 at that time and orthogonal to the vertical direction is defined as reference plane S1. When slide piece 6 moves in the direction of arrow a2 from this state, contact piece 7 displaces downward along second guide surface 602 as indicated by “P22” and “P23”.

Then, after reaching the lower end of slide piece 6, that is, reaching a position indicated by “P24”, contact piece 7 displaces upward as indicated by “P25” and “P26”. When contact piece 7 moves to the position indicated by “P26” from the position indicated by “P24” during the upward displacement, contact piece 7 is swiftly flipped upward by the elastic force of vibrating body 4 which remains warped. Therefore, even after slide piece 6 moves to the first position, that is, contact piece 7 moves to the position indicated by “P26”, contact piece 7 continues to vibrate in the vertical direction by the elasticity of vibrating body 4. However, the vibration of contact piece 7 gradually attenuates. When the vibration of contact piece 7 is stopped, contact piece 7 stops at the position indicated by “P26”, that is, the position where the center axis (center of virtual circle P26) of contact piece 7 passes through reference plane S1.

As described above, when slide piece 6 passes over contact piece 7 in the horizontal direction during the movement from the second position to the first position, contact piece 7 being in contact with slide piece 6 rides over slide piece 6, thereby moving in the vertical direction. Due to contact piece 7 being provided to vibrating body 4, after slide piece 6 passes over contact piece 7, vibrating body 4 is vibrated in the vertical direction, and the vibration energy of vibrating body 4 is converted into electrical energy by piezoelectric element 5. Thus, power generation device 1 generates power.

As described above, in power generation device 1 and electronic device 10 according to the present exemplary embodiment, operation unit 3 moves to the operation position illustrated in FIG. 5D from the reference position illustrated in FIG. 5A, and then, returns to the reference position, due to the operation for operation unit 3 by operator 100. During a sequence of movements of operation unit 3 described above, slider 60 linearly reciprocates between the start position and the terminal position along the horizontal direction. During the reciprocating movement of slider 60, slide piece 6 reciprocates between the first position and the second position. That is, slide piece 6 moves to the second position from the first position, and then, turns and moves to the first position from the second position. Thus, power generation device 1 generates power in both of an “outbound path” in which slide piece 6 moves to the second position from the first position and a “return path” in which slide piece 6 moves to the first position from the second position.

Herein, about 10 ms is enough for the time for piezoelectric element 5 to generate power due to the vibration of vibrating body 4, for example, although such a time depends on the frequency of vibration of vibrating body 4. That is, if the frequency of vibration of vibrating body 4 is sufficiently high, sufficient power generation is possible even in relatively a short period. Therefore, even when operation unit 3 is moved to the operation position from the reference position due to the operation for operation unit 3 by operator 100, and just after that, the operation for operation unit 3 by operator 100 is canceled, power generation device 1 can generate power in a short period in which slide piece 6 is at the second position.

In the present exemplary embodiment, maximum displacement amount L1 of contact piece 7 in the vertical direction when slide piece 6 moves to the second position from the first position and maximum displacement amount L2 of contact piece 7 in the vertical direction when slide piece 6 moves to the first position from the second position are equal to each other. Specifically, the relative positional relation between slide piece 6 and contact piece 7 in the vertical direction is specified such that reference plane S1 is at a position where slide piece 6 is vertically bisected. It should be noted that the wording “equal” includes not only a strictly equal state but also a substantially equal state within a margin of error.

In addition, in electronic device 10 according to the present exemplary embodiment, when operation unit 3 moves to the operation position from the reference position, switch 12 is turned on. Then, due to the movement of operation unit 3 to the reference position from the operation position, switch 12 is turned off. Specifically, the state of switch 12 is sequentially changed to be off, on, and off with the operation of operation unit 3, by which a prescribed signal is input to signal processing circuit 11. According to this configuration, operator 100 can input the prescribed signal to signal processing circuit 11 as well as activate signal processing circuit 11 by starting the power generation by power generation device 1, through the operation for operation unit 3.

In this case, signal processing circuit 11 is activated by power generated by power generation device 1 in the “outbound path” where slide piece 6 moves to the second position from the first position. That is, at the point when switch 12 is turned on, signal processing circuit 11 is already activated. Therefore, signal processing circuit 11 can detect that switch 12 is turned on. Note that signal processing circuit 11 may be activated by the prescribed signal being input to signal processing circuit 11. In this case, a start switch for supplying power to a portion of signal processing circuit 11 is provided. The portion of signal processing circuit 11 is activated by the prescribed signal being input to the start switch.

### (3) Effect

According to power generation device 1 described above in the present exemplary embodiment, vibrating body 4 can be vibrated in the vibration direction (vertical direction) with the movement of slide piece 6 from the first position to the second position along the sliding direction (horizontal direction). An amount of movement of slide piece 6 in the sliding direction at that time may be equal to or more than a value obtained by adding the size of contact piece 7 in the sliding direction to the size of slide piece 6 in the sliding direction to enable contact piece 7 to ride over slide piece 6. In other words, the amount of movement of slide piece 6 in the sliding direction may be a length enough for contact piece 7 to ride over slide piece 6. The amount of movement of slide piece 6 and the amplitude of the vibration of vibrating body 4 do not directly relate to each other, and thus, a decrease in the amount of movement of slide piece 6 does not directly lead to a reduction in the power generation amount. Therefore, the space for the movement of slide piece 6 can be reduced. Accordingly, power generation device 1 that can suppress a reduction in the power generation amount while enabling a reduction in size can be implemented.

Further, a power generation device requiring a rotary member (the gear in PTL 1 and rotation weight and exciting lever in PTL 2) needs a relatively complex structure such as a rotation shaft and a bearing for rotating the rotary member. On the other hand, power generation device 1 according to the present exemplary embodiment only needs the movement of slide piece 6 in a straight line, and thus, can vibrate vibrating body 4 with a relatively simple structure.

In addition, as in the present exemplary embodiment, it is preferable that one surface of slide piece 6 in the vibration direction serves as first guide surface 601 inclined with respect to the sliding direction so as to face contact piece 7 in the sliding direction when slide piece 6 is at the first position. According to this configuration, slide piece 6 is brought into contact with contact piece 7 at first guide surface 601 during the movement of slide piece 6 from the first position to the second position. Therefore, when slide piece 6 moves to the second position from the first position, slide piece 6 can gradually displace contact piece 7 in the vibration direction along first guide surface 601 while warping vibrating body 4. However, this configuration is not always necessary for power generation device 1, and power generation device 1 may not have first guide surface 601.

In addition, as in the present exemplary embodiment, it is preferable that one surface of slide piece 6 in the vibration direction serves as second guide surface 602 inclined with respect to the sliding direction so as to face contact piece 7 in the sliding direction when the slide piece 6 is at the second position. According to this configuration, slide piece 6 is brought into contact with contact piece 7 at second guide surface 602 during the movement of slide piece 6 from the second position to the first position. Therefore, when slide piece 6 moves to the first position from the second position, slide piece 6 can gradually displace contact piece 7 in the vibration direction along second guide surface 602 while warping vibrating body 4. Accordingly, power generation device 1 can vibrate vibrating body 4, thereby being capable of generating power by piezoelectric element 5, also during the movement of slide piece 6 from the second position to the first position. Consequently, the power generation amount of power generation device 1 during the reciprocating movement of slide piece 6 between the first position and the second position is increased. In addition, due to slide piece 6 and contact piece 7 being shared by both the outbound path and the return path of slide piece 6, it is unnecessary to separately provide configurations for vibrating vibrating body 4 for the outbound path and the return path of slide piece 6, which leads to downsizing of power generation device 1. However, this configuration is not always necessary for power generation device 1, and power generation device 1 may not have second guide surface 602.

Moreover, as in the present exemplary embodiment, it is preferable that power generation device 1 further has return spring 8 that applies, to slide piece 6, a force for moving slide piece 6 to the first position when slide piece 6 is at the second position. According to this configuration, after moving to the second position from the first position, slide piece 6 automatically returns (moves) to the first position by the elastic force of return spring 8. Therefore, power generation device 1 can repeatedly generate power. However, this configuration is not always necessary for power generation device 1, and power generation device 1 may not have return spring 8.

In this case, it is preferable that operation unit 3 is movable from the reference position to the operation position as in the present exemplary embodiment. In this case, it is preferable that slide piece 6 moves in conjunction with operation unit 3 so as to be at the first position when operation unit 3 is at the reference position, and so as to be at the second position when operation unit 3 is at the operation position. In this case, it is preferable that return spring 8 applies, to operation unit 3, a force for moving operation unit 3 to the reference position when operation unit 3 is at the operation position. According to this configuration, after moving to the operation position from the reference position, operation unit 3 automatically returns (moves) to the reference position by the elastic force of return spring 8. Accordingly, operator 100 does not need to perform an operation for returning operation unit 3 to the reference position from the operation position. However, this configuration is not always necessary for power generation device 1, and operation unit 3 may not return by the elastic force of return spring 8.

In addition, it is preferable that, as in the present exemplary embodiment, power generation device 1 further has link mechanism 9 for causing slide piece 6 to move in conjunction with operation unit 3, and operation unit 3 has a plurality of operation elements 301 and 302 each of which is movable in relation to housing 2. In this case, it is preferable that link mechanism 9 moves slide piece 6 in the sliding direction by the movement of at least one of the plurality of operation elements 301 and 302. According to this configuration, slide piece 6 can be shared by the plurality of operation elements 301 and 302, whereby the number of components of power generation device 1 can be reduced. Accordingly, a number of man-hours for assembly of power generation device 1 can be reduced. However, this configuration is not always necessary for power generation device 1, and a plurality of slide pieces 6 may be provided corresponding to the plurality of operation elements 301 and 302.

In addition, it is preferable that the sliding direction and the vibration direction are mutually orthogonal as in the present exemplary embodiment. According to this configuration, the amount of movement of slide piece 6 in the sliding direction can be further reduced, which leads to downsizing of power generation device 1.

In addition, it is preferable that, as in the present exemplary embodiment, maximum displacement amount L1 of contact piece 7 in the vibration direction when slide piece 6 moves to the second position from the first position and maximum displacement amount L2 of contact piece 7 in the vibration direction when slide piece 6 moves to the first position from the second position are equal to each other. According to this configuration, the amplitude of vibration of vibrating body 4 is the same between during the movement of slide piece 6 to the second position from the first position and during the movement of slide piece 6 to the first position from the second position. Thus, power generation device 1 can generate power in the same amount between during the movement of slide piece 6 to the second position from the first position and during the movement of slide piece 6 to the first position from the second position.

In addition, it is preferable that, as in the present exemplary embodiment, slide piece 6 is disposed to form gaps G1 and G2 between slide piece 6 and contact piece 7 respectively at the first position and the second position. According to this configuration, the contact of contact piece 7 with slide piece 6 can be avoided when slide piece 6 is at the first position and when slide piece 6 is at the second position. Therefore, the attenuation of vibration of vibrating body 4 due to the contact between slide piece 6 and contact piece 7 can be prevented, resulting in that the power generation amount by piezoelectric element 5 increases. However, this configuration is not always necessary for power generation device 1, and slide piece 6 may be in contact with contact piece 7 on at least one of the first position and the second position.

In addition, it is preferable that, as in the present exemplary embodiment, housing 2 has first case 21 that holds vibrating body 4, and second case 22. Second case 22 has operation unit 3 mounted thereto such that a portion of operation unit 3 is exposed to the outside of housing 2, and is joined to first case 21 to form housing 2 together with first case 21. According to this configuration, during the assembly of power generation device 1, first case 21 provided with vibrating body 4 and second case 22 provided with operation unit 3 are joined, whereby power generation device 1 can be constructed. Thus, the number of man-hours for assembly of power generation device 1 can be re duce d.

In this case, it is preferable that, as in the present exemplary embodiment, slide piece 6 moves in conjunction with operation unit 3 and is a portion of slider 60 that moves in a straight line along the sliding direction in relation to housing 2, and slider 60 is stored in second case 22. According to this configuration, first case 21 and second case 22 can be joined with slider 60 being stored in second case 22 to construct power generation device 1. Thus, the number of man-hours for assembly of power generation device 1 can be re duce d.

It is also preferable that, as in the present exemplary embodiment, the combination of contact piece 7 and slide piece 6 is provided at a plurality of locations distant from each other in a width direction orthogonal to both the sliding direction and the vibration direction in housing 2. According to this configuration, the combination of contact piece 7 and slide piece 6 is provided at a plurality of locations (at both sides, that is, at two locations in the first exemplary embodiment) in the width direction, whereby vibrating body 4 is flipped in the vibration direction at a plurality of locations in the width direction. Thus, the vibration of vibrating body 4 is stabilized, compared to a configuration where vibrating body 4 is flipped at one location in the width direction.

It is also preferable that, as in the present exemplary embodiment, electronic device 10 includes power generation device 1, and signal processing circuit 11 electrically connected to piezoelectric element 5 of power generation device 1. According to this configuration, electronic device 10 that can suppress a reduction in the power generation amount while enabling a reduction in size can be implemented. In addition, electronic device 10 achieves a reduction in capacity or unnecessity of a battery for driving signal processing circuit 11, for example.

It is also preferable that, as in the present exemplary embodiment, signal processing circuit 11 is stored in housing 2, and has switch 12 that is switched between on and off in conjunction with operation unit 3. According to this configuration, signal processing circuit 11 can detect an operating state of operation unit 3 by switch 12 and receive an input from operator 100.

### (4) Modification

Modifications of the first exemplary embodiment will be described below.

The operating mechanism of power generation device 1 is not limited to a momentary operating mechanism in which switch 12 is in an on state only while operation unit 3 is pressed as described in the first exemplary embodiment. The operating mechanism of power generation device 1 may be an alternate operating mechanism in which switch 12 keeps its on state even after a force for pressing operation unit 3 becomes absent, for example. With the alternate operating mechanism, when operation unit 3 is pressed once, slide piece 6 moves to the second position from the first position, and when operation unit 3 is again pressed, slide piece 6 moves to the first position from the second position. Switch 12 is not limited to a normally open switch as in the first exemplary embodiment, and may be a normally closed switch that is on when operation unit 3 is not pressed and is off when operation unit 3 is pressed.

Further, the shape of slide piece 6 is not limited to the shape described in the first exemplary embodiment and can be modified as appropriate. For example, first guide surface 601 and second guide surface 602 may be respectively provided on one surface of slide piece 6 in the vibration direction, and first guide surface 601 and second guide surface 602 may be provided on the same surface of slide piece 6. That is, the sectional shape of slide piece 6 in the direction orthogonal to the width direction may be an up-pointing triangle, for example. In this case, both first guide surface 601 and second guide surface 602 are provided on the top surface of slide piece 6. According to this configuration, contact piece 7 displaces in one direction (upward) in the vibration direction during the movement of slide piece 6 from the first position to the second position and during the movement of slide piece 6 from the second position to the first position.

In addition, slide piece 6 may not have second guide surface 602. In this case, contact piece 7 (vibrating body 4) is vibrated only during the movement of slide piece 6 from the first position to the second position. With this configuration, power generation device 1 generates power only when slide piece 6 moves in one direction in the sliding direction.

In addition, slide piece 6 may not have both first guide surface 601 and second guide surface 602. Specifically, the sectional shape of slide piece 6 in the direction orthogonal to the width direction may be circular or elliptical, for example. According to this configuration as well, with the movement of slide piece 6 in the sliding direction, contact piece 7 being in contact with slide piece 6 rides over slide piece 6, thereby moving in the vibration direction, whereby vibrating body 4 is vibrated in the vibration direction.

Moreover, it is not always necessary that housing 2 has first case 21 and second case 22. Housing 2 may be composed of a single case or three or more cases, for example. If housing 2 is formed by using a plurality of cases, it is not limited to join the plurality of cases by laser welding as described in the first exemplary embodiment. The plurality of cases may be joined by ultrasonic welding, heat welding, or solvent welding, for example.

It is also preferable that, to ensure high amplitude of vibration of vibrating body 4, a weight is attached to the free end (right end in the present exemplary embodiment) of elastic plate 41. The weight may not separately be provided to contact piece 7, and contact piece 7 may also be used as the weight.

The configuration in which the combination of contact piece 7 and slide piece 6 is provided at two locations distant from each other in the width direction is not always necessary for power generation device 1. Power generation device 1 may have one or more combinations of contact piece 7 and slide piece 6. For example, a hole may be formed on the central part of vibrating body 4 in the width direction, and contact piece 7 may be formed on a part of the peripheral edge of the hole. In this configuration, slider 60 is formed with a protrusion inserted into the hole, and slide piece 6 is formed at the tip of the protrusion.

Contact piece 7 is provided at the free end (right end in the first exemplary embodiment) of vibrating body 4. However, the present disclosure is not limited thereto, and contact piece 7 may be provided at the central part of vibrating body 4 in the sliding direction, for example.

In the first exemplary embodiment, vibrating body 4 is a flat plate which is substantially linear in a plan view. However, it is not limited thereto, and vibrating body 4 may be formed such that a part thereof is curved or bent.

In addition, operation unit 3 is not limited to be formed on the top surface of housing 2 and may be provided on the side surface or the bottom surface of housing 2. If operation unit 3 is formed on the side surface of housing 2, operation unit 3 may move between the reference position and the operation position along the sliding direction. In this case, operation unit 3 and slider 60 may be integrally formed. Moreover, operation unit 3 is not limited to be a push button, and may have a sliding structure or a see-saw structure, for example. In any case, slide piece 6 is configured to move in the sliding direction in conjunction with operation unit 3. If operation unit 3 has the sliding structure, operation unit 3 and slider 60 may be integrally formed.

In addition, operation unit 3 is not limited to have two operation elements 301 and 302 as in the first exemplary embodiment, and may have three or more operation elements. Alternatively, operation unit 3 may have only a single operation element. In this case, the operation element and operation unit 3 are synonymous.

In addition, power generation device 1 is not limited to have the configuration where slide piece 6 moves to the second position from the first position when operation unit 3 moves to the operation position from the reference position. Slide piece 6 may move to the first position from the second position when operation unit 3 moves to the operation position from the reference position. That is, slide piece 6 only needs to move in the sliding direction in conjunction with operation unit 3, and may be configured to move to the first position from the second position when operation unit 3 is operated (button 31 is pressed).

In the first exemplary embodiment, the center of slide piece 6 is disposed on an extension line of the sliding direction of contact piece 7. However, the center of slide piece 6 may be shifted from the extension line of the sliding direction of contact piece 7. Specifically, maximum displacement amount L1 of contact piece 7 in the vibration direction when slide piece 6 moves to the second position from the first position and maximum displacement amount L2 of contact piece 7 in the vibration direction when slide piece 6 moves to the first position from the second position may be different from each other.

In addition, the sliding direction and the vibration direction may not be mutually orthogonal. That is, power generation device 1 is not limited to have the configuration where vibrating body 4 is disposed parallel to the sliding direction as described in the first exemplary embodiment. Vibrating body 4 may be inclined with respect to the sliding direction.

Link mechanism 9 is not limited to be constituted by pressing surface 314 and inclined surface 63. Any configuration that causes slide piece 6 to move in conjunction with operation unit 3 may be applied. For example, link mechanism 9 may have a configuration for causing slider 60 to move in the sliding direction in conjunction with the movement of operation unit 3 along the sliding direction.

Power generation device 1 is not limited to be used for electronic device 10, and may be used stand-alone, or may be built in a device and facility other than electronic device 10.

In addition, electronic device 10 is not limited to be configured such that signal processing circuit 11 is stored in housing 2 as in the first exemplary embodiment, and may be configured such that a portion of or entire signal processing circuit 11 is provided outside housing 2. Signal processing circuit 11 may include electronic components composing a sensor, an AD converter, a

DA converter, a receiving circuit, and the like, in addition to the electronic components composing the power supply circuit, the control circuit, the memory, a communication circuit, and the like.

In addition, switch 12 in signal processing circuit 11 may not be switched in conjunction with operation unit 3. For example, an operation unit for operating switch 12 may be provided separately from operation unit 3 of power generation device 1. Switch 12 is not limited to be mounted on printed substrate 13, and may be a membrane switch using a conductor layer formed on printed substrate 13, for example.

In addition, electronic device 10 is not limited to be outdoor use, and a waterproof structure is not always necessary. Accordingly, waterproof rubber 32 at operation unit 3 may be eliminated.

### Second Exemplary Embodiment

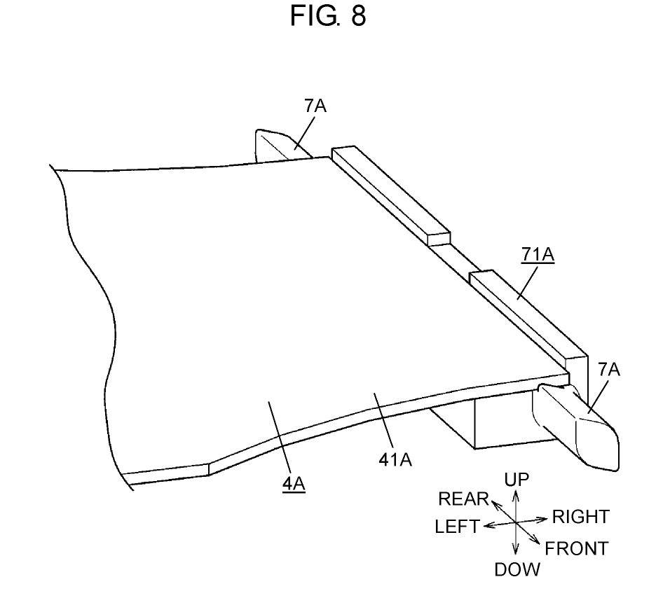

Power generation device 1 according to the present exemplary embodiment is different from the power generation device in the first exemplary embodiment in that, as illustrated in FIG. 8, contact piece 7A and vibrating body 4A are different members and contact piece 7A is joined to vibrating body 4A. Hereinafter, elements similar to those in the first exemplary embodiment are given identical reference signs, and description of such elements is omitted as appropriate. “Contact piece 7A”, “vibrating body 4A”, and “elastic plate 41A” in the second exemplary embodiment respectively correspond to “contact piece 7”, “vibrating body 4”, and “elastic plate 41” in the first exemplary embodiment.

In the second exemplary embodiment, contact piece 7A is a part of contact member 71A. Contact member 71A is fixed to a free end (right end) of vibrating body 4A (elastic plate 41A). Contact member 71A is formed from a synthetic resin. Contact member 71A is joined to elastic plate 41A by laser welding, for example.

Contact piece 7A is provided at both ends of contact member 71A in the front-rear direction. The sectional shape of contact piece 7A orthogonal to the front-rear direction is a parallelogram. Corners (lower-left corner and upper-right corner) of contact piece 7A which is in contact with slide piece 6 are rounded to have a curved surface. However, the configuration in which the corners (lower-left corner and upper-right corner) of contact piece 7A which is in contact with slide piece 6 are rounded to have a curved surface is not always necessary for power generation device 1.

In power generation device 1 according to the second exemplary embodiment described above, contact piece 7A and vibrating body 4A are different members, so that the degree of freedom in designing the shape of contact piece 7A is improved. In addition, contact piece 7A being formed from a synthetic resin provides an effect of suppressing wear of slide piece 6 caused by the contact with contact piece 7A.

It is to be noted that contact piece 7A (contact member 71A) is not limited to be formed from a synthetic resin, and may be metallic, like elastic plate 41A, for example.

Other configurations and functions are the same as those of the above-described first exemplary embodiment. The configuration described in the second exemplary embodiment is applicable by being combined with the respective configurations (including modifications) described in the first exemplary embodiment.

### REFERENCE MARKS IN THE DRAWINGS

1: power generation device
2: housing
3: operation unit
4, 4A: vibrating body
5: piezoelectric element
6: slide piece
7, 7A: contact piece
8: return spring
9: link mechanism
10: electronic device
11: signal processing circuit
12: switch
21: first case
22: second case
60: slider
301, 302: operation element
601: first guide surface
602: second guide surface
G1, G2: gap
L1, L2: maximum displacement amount

1. A power generation device comprising:
a housing;
an operation unit that is movable in relation to the housing;
a cantilevered vibrating body that has elasticity and is partly fixed to the housing;
a piezoelectric element that is provided to the vibrating body and converts vibration energy of the vibrating body into electrical energy when the vibrating body is vibrated in a vibration direction;
a slide piece that moves in conjunction with the operation unit and moves in a straight line between a first position and a second position in a sliding direction that intersects the vibration direction in relation to the housing; and
a contact piece that is provided to the vibrating body, the contact piece being on a trajectory of the slide piece when the slide piece moves in the straight line, and being configured so as to be in contact with the slide piece and ride over the slide piece to move in the vibration direction, when the slide piece moves from the first position to the second position.

2. The power generation device according to claim 1, wherein one surface of the slide piece in the vibration direction is a first guide surface inclined with respect to the sliding direction so as to face the contact piece in the sliding direction when the slide piece is at the first position.

3. The power generation device according to claim 1, wherein one surface of the slide piece in the vibration direction is a second guide surface inclined with respect to the sliding direction so as to face the contact piece in the sliding direction when the slide piece is at the second position.

4. The power generation device according to claim 1, further comprising a return spring that applies, to the slide piece, a force for moving the slide piece to the first position when the slide piece is at the second position.

5. The power generation device according to claim 4, wherein
the operation unit is movable from a reference position to an operation position,
the slide piece moves in conjunction with the operation unit so as to be at the first position when the operation unit is at the reference position, and so as to be at the second position when the operation unit is at the operation position, and
the return spring applies, to the operation unit, a force for moving the operation unit to the reference position when the operation unit is at the operation position.

6. The power generation device according to claim 1, further comprising a link mechanism that causes the slide piece to move in conjunction with the operation unit,
wherein
the operation unit has a plurality of operation elements each of which is movable in relation to the housing, and
the link mechanism moves the slide piece in the sliding direction by a movement of at least one of the plurality of operation elements.

7. The power generation device according to claim 1, wherein the sliding direction and the vibration direction are mutually orthogonal.

8. The power generation device according to claim 1, wherein a maximum displacement amount of the contact piece in the vibration direction when the slide piece moves to the second position from the first position and a maximum displacement amount of the contact piece in the vibration direction when the slide piece moves to the first position from the second position are equal to each other.

9. The power generation device according to claim 1, wherein the slide piece is disposed such that a gap is formed between the slide piece and the contact piece at the first position and at the second position.

10. A power generation device according to claim 1, wherein
the housing has:
a first case that holds the vibrating body; and
a second case to which the operation unit is mounted with a portion of the operation unit being exposed to an outside of the housing, the second case being joined to the first case to constitute the housing together with the first case.

11. The power generation device according to claim 10, wherein
the slide piece is a part of a slider that moves in conjunction with the operation unit and moves in the straight line in the sliding direction in relation to the housing, and
the slider is stored in the second case.

12. The power generation device according to claim 1, wherein a combination of the contact piece and the slide piece is provided at a plurality of locations distant from each other in a width direction orthogonal to both the sliding direction and the vibration direction in the housing.

13. An electronic device comprising:
the power generation device according to claim 1; and
a signal processing circuit electrically connected to the piezoelectric element of the power generation device.

14. The electronic device according to claim 13, wherein the signal processing circuit is stored in the housing and has a switch which is switched between on and off in conjunction with the operation unit.
